(19) United States
(12) Patent Application Publication
(10) Pub. No.: US 2026/0136778 A1
(43) Pub. Date: May 14, 2026

(54) DISPLAY PANEL AND METHOD OF MANUFACTURING THE SAME

(71) Applicants: Beijing BOE Technology Development Co., Ltd., Beijing (CN); BOE Technology Group Co., Ltd., Beijing (CN)

(72) Inventors: Donghui YU, Beijing (CN); Menghua ZHAO, Beijing (CN); Cheng XU, Beijing (CN); Dandan ZHOU, Beijing (CN); Juanjuan YOU, Beijing (CN)

(21) Appl. No.: 18/695,482

(22) PCT Filed: Aug. 24, 2023
(86) PCT No.: PCT/CN2023/114750

§ 371 Date: Mar. 26, 2024

(51) Int. Cl. H10K 59/124; H10K 59/12; H10K 59/80

(52) U.S. Cl. CPC H10K 59/124; H10K 59/1201; H10K 59/879

(57) ABSTRACT

The present application discloses a display panel and a method of manufacturing the same. The display panel includes a first substrate, a planarization layer, a first electrode, a light-emitting layer, and a second electrode sequentially provided. The planarization layer has a non-flat surface facing away from the first substrate. The first electrode conforms to the planarization layer. The light-emitting layer conforms to the first electrode. The second electrode conforms to the light-emitting layer.

### CROSS-REFERENCE TO RELATED APPLICATIONS

This application is the U.S. national phase of PCT Application No. PCT/CN2023/114750 filed on Aug. 24, 2023, the disclosure of which is incorporated herein by reference in its entirety.

### TECHNICAL FIELD

This application relates to the field of display technology, and in particular to a display panel and a method of manufacturing the same.

### BACKGROUND

Display panels, such as OLEDs (Organic Light-Emitting Diodes), or QLEDs (Quantum Dot Light-Emitting Diodes), have been more and more widely used in various display devices such as mobile phones, tablets, computers and televisions due to self-luminescence thereof.

However, the self-luminous display panels generally have a low light extraction efficiency.

### SUMMARY

The present application aims to provide a display panel with a high light extraction efficiency and a method of manufacturing the same.

The present application discloses a display panel, including:
a first substrate;
a planarization layer on a side of the first substrate and including a first planarization layer close to the first substrate and a second planarization layer away from the first substrate, where the first planarization layer has a flat surface on a side close to the second planarization layer, and the second planarization layer has a concave-convex profile;
a first electrode on a side of the planarization layer away from the first substrate, the first electrode continuing the concave-convex profile of the planarization layer;
a light-emitting layer on a side of the first electrode away from the first substrate, the light-emitting layer continuing the concave-convex profile of the first electrode; and
a second electrode on a side of the light-emitting layer away from the first electrode, the second electrode continuing the concave-convex profile of the light-emitting layer.

Optionally, the display panel further includes a pixel definition layer between the first electrode and the light-emitting layer and defining a pixel area and a non-pixel area, where the concave-convex profile of the planarization layer is in the pixel area.

Optionally, the concave-convex profile of the planarization layer includes a plurality of first convex structures that are convex towards the first electrode.

Optionally, a height of each of the first convex structures in a first direction is less than or equal to a thickness of the second planarization layer.

Optionally, the display panel further includes an isolation layer between the first planarization layer and the second planarization layer, where the isolation layer has a thickness less than or equal to 500 nm.

Optionally, an angle between a portion of an outer surface of each of the first convex structures and a first direction is greater than or equal to 40° and less than or equal to 60°.

Optionally, orthographic projections of the plurality of first convex structures in a first direction are distributed in an edge area of an orthographic projection of the pixel area in the first direction.

Optionally, orthographic projections of the plurality of first convex structures in a first direction are distributed all over an orthographic projection of the pixel area in the first direction.

Optionally, the display panel further includes a fill layer on a side of the second electrode away from the light-emitting layer, where a lens structure is provided in the fill layer and protrudes in a direction away from the second electrode.

Optionally, an orthographic projection of the lens structure in a first direction partially overlaps the pixel area with an overlapping area greater than or equal to half of an area of the orthographic projection of the lens structure in the first direction and less than the area of the orthographic projection of the lens structure in the first direction, and the lens structure covers a portion of the concave-convex profile.

Optionally, a plurality of lens structures are provided in the fill layer, and are disposed on a periphery of the pixel area.

Optionally, the lens structure has a refractive index greater than a refractive index of an area in the fill layer other than the lens structure.

Optionally, the fill layer includes a first fill layer on the side of the second electrode away from the light-emitting layer, and a second fill layer on a side of the first fill layer away from the second electrode; the lens structure is in the second fill layer; and the first fill layer includes a second convex structure that is convex towards the second electrode, where an orthographic projection of the second convex structure in a first direction is on a side of the lens structure away from the pixel area.

Optionally, the first fill layer includes a plurality of second convex structures, orthographic projections of the plurality of second convex structures in the first direction being disposed on a periphery of the lens structure.

Optionally, the first electrode is a reflective electrode, and the second electrode is a transmissive electrode.

Optionally, the first electrode is a transmissive electrode, and the second electrode is a reflective electrode.

The present application further discloses a method of manufacturing a display panel, including:
providing a first substrate;
forming a planarization layer, a first electrode, a light-emitting layer, and a second electrode sequentially on a side of the first substrate, where the planarization layer has a concave-convex profile, and the first electrode, the light-emitting layer, and the second electrode continue the concave-convex profile of the planarization layer.

Optionally, the planarization layer includes a first planarization layer, an isolation layer, and a second planarization layer; and when the planarization layer is prepared, a negative photoresist is coated on the side of the first substrate and is exposed and developed to form the first planarization layer, the isolation layer is prepared on a side of the first planarization layer away from the first substrate, and a positive photoresist is coated on a side of the isolation layer away from the first planarization layer and is exposed and developed to form the second planarization layer having the concave-convex profile.

Optionally, the method of manufacturing the display panel includes: forming an encapsulation layer on a side of the second electrode away from the light-emitting layer; forming a lens structure on a side of the encapsulation layer away from the second electrode; forming a fill layer on the side of the encapsulation layer away from the second electrode to wrap the lens structure; and providing a second substrate on a side of the fill layer away from the encapsulation layer.

Optionally, the method of manufacturing the display panel includes: providing a second substrate; forming a second fill layer on a side of the second substrate, where the second fill layer has a concave structure on a side away from the second substrate; forming a first fill layer on the side of the second fill layer away from the second substrate, where the first fill layer fills the concave structure to form a lens structure; and bonding the first substrate to the second substrate with the first fill layer.

Compared with the related art, the present application makes it easy to prepare the concave-convex profile with a double planarization layer structure, such that the first electrode, the light-emitting layer, and the second electrode form concave-convex profiles. An original light propagation path is changed by reflection and refraction of the concave-convex profiles to reduce light propagating at a large angle, thereby reducing total reflection within the display panel and improving a light extraction efficiency of the display panel.

It is to be understood that the above general description and the following detailed description are exemplary and explanatory only, and are not intended to limit this specification.

### BRIEF DESCRIPTION OF DRAWINGS

The accompanying drawings, which are incorporated into and constitute a part of this specification, illustrate embodiments consistent with the specification and, together with the specification, serve to explain the principles of the specification.

FIG. 1 is a schematic structural diagram of a display panel according to an embodiment of the present application.

FIG. 2 is a schematic structural diagram of a display panel according to another embodiment of the present application.

FIG. 3 is a schematic structural diagram of a display panel according to another embodiment of the present application.

FIG. 4 is a schematic structural diagram of a display panel according to another embodiment of the present application.

FIG. 5 is a schematic structural diagram of a display panel according to another embodiment of the present application.

FIG. 6 is a schematic top view illustrating an arrangement of lens structures in a display panel according to an embodiment of the present application.

FIG. 7 is a schematic top view illustrating an arrangement of lens structures in a display panel according to another embodiment of the present application.

FIG. 8 is a schematic top view illustrating an arrangement of first convex structures in a display panel according to an embodiment of the present application.

FIG. 9 is a schematic top view illustrating an arrangement of first convex structures in a display panel according to another embodiment of the present application.

FIG. 10 is a schematic diagram illustrating a process of manufacturing a display panel according to an embodiment of the present application.

FIG. 11 is a schematic diagram illustrating a process of manufacturing a planarization layer of a display panel according to an embodiment of the present application.

FIG. 12 is a schematic diagram illustrating a process of manufacturing a partial structure of a display panel according to an embodiment of the present application.

FIG. 13 is a schematic diagram illustrating a process of manufacturing a partial structure of a display panel according to another embodiment of the present application.

FIG. 14 is a schematic diagram illustrating a process of manufacturing a partial structure of a display panel according to yet another embodiment of the present application.

Description of reference numerals: 10—first substrate; 11—color filter layer; 20—planarization layer; 21—first planarization layer; 22—second planarization layer; 221—first convex structure; 23—isolation layer; 30—first electrode; 40—pixel definition layer; 41—boss; 50—light-emitting layer; 60—second electrode; 70—encapsulation layer; 71—first inorganic encapsulation layer; 72—first organic encapsulation layer; 73—second inorganic encapsulation layer; 80—fill layer; 81—lens structure; 82—first fill layer; 83—second fill layer; 84—second convex structure; 90—second substrate; 100—pixel area; 200—non-pixel area.

### DETAILED DESCRIPTION

Reference will now be made in detail to exemplary embodiments, examples of which are illustrated in the accompanying drawings. When the following description refers to the drawings, the same numerals in different drawings indicate the same or similar elements, unless otherwise indicated. Embodiments described in the following exemplary embodiments are not intended to represent all embodiments consistent with the specification. Rather, they are merely examples of apparatuses and methods consistent with some aspects of the specification as detailed in the appended claims.

Terminology used in the present application is for the purpose of describing particular embodiments only and is not intended to be limiting of the present disclosure. Unless otherwise defined, technical or scientific terms used herein shall have their ordinary meanings as understood by a person of ordinary skill in the art to which the present application pertains. Terms “first,” “second,” and the like as used in this specification and in the claims do not imply any order, quantity, or importance, but are merely used to distinguish one component from another. Similarly, terms “a” or “an” and the like do not denote a limitation on quantity, but rather denote the presence of at least one. “A plurality of” or “several” means two or more. Unless otherwise indicated, terms “front,” “rear,” “lower,” and/or “upper” and the like are for convenience of description only and are not limited to a position or a spatial orientation. Terms “including” or “comprising” and the like are intended to mean that elements or items appearing before “including” or “comprising” encompass elements or items listed after “including” or “comprising” and equivalents thereof, without excluding other elements or items. Terms “connected” or “coupled” and the like are not limited to physical or mechanical connections, but may include electrical connections, whether direct or indirect.

Terminology used in this specification is for the purpose of describing particular embodiments only and is not intended to be limiting of the present disclosure. As used in this specification and the appended claims, the singular forms of “a,” “an,” “the,” and “said” are intended to include plural forms as well, unless the context clearly dictates otherwise. It should also be understood that the term “and/or” as used herein refers to and includes any or all possible combinations of one or more of the associated listed items.

In the related art, display panels have a low light extraction efficiency due to waveguide effect and total reflection.

In order to solve the above technical problem, the present application provides a display panel, including:
a first substrate 10;
a planarization layer 20 on the first substrate 10 and including a first planarization layer 21 and a second planarization layer 22, the second planarization layer 22 being farther away from the first substrate 10 than the first planarization layer 21, where the first planarization layer 21 has a flat surface facing the second planarization layer 22, and the second planarization layer 22 has a non-flat surface facing away from the first planarization layer 21;
a first electrode 30 on the planarization layer 20 away from the first substrate 10, the first electrode 30 conforming to the planarization layer 20;
a light-emitting layer 50 on the first electrode 30 away from the planarization layer 20, the light-emitting layer 50 conforming to the first electrode 30; and
a second electrode 60 on the light-emitting layer 50 away from the first electrode 30, the second electrode 60 conforming to the light-emitting layer 50.

With the present application, the non-flat surface is easy to prepare with a double planarization layer structure, such that the first electrode, the light-emitting layer, and the second electrode form non-flat surfaces. An original light propagation path is changed by reflection and refraction of the non-flat surfaces to reduce light propagating at a large angle, thereby reducing total reflection within the display panel and improving a light extraction efficiency of the display panel.

Embodiments of the present application consistent with the above inventive concept will be described in detail below.

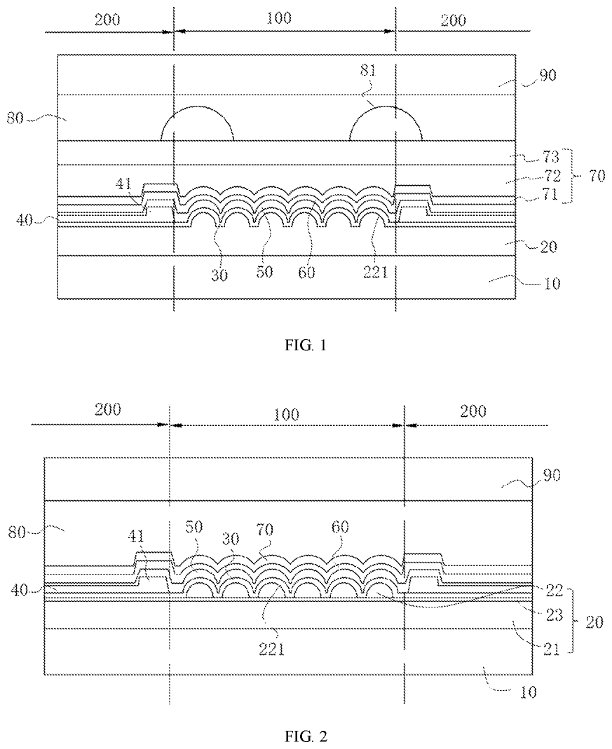

As shown in FIG. 1, the first substrate 10 may be a rigid first substrate. The rigid first substrate may be a glass first substrate or a PMMA (polymethyl methacrylate) first substrate. However, the first substrate 10 may be a flexible first substrate. The flexible first substrate may be a PET (polyethylene terephthalate) first substrate, a PEN (polyethylene naphthalate two formic acid glycol ester) first substrate, or a PI (polyimide) first substrate.

As shown in FIG. 1, the planarization layer 20 is on the first substrate 10. In an exemplary embodiment, a driving structure layer (not shown in the drawings) is provided between the first substrate 10 and the planarization layer 20. A specific structure of the driving structure layer is set flexibly according to actual needs, which is not limited in the present application. The planarization layer 20 covers the first substrate 10, and has a non-flat surface facing away from the first substrate 10 which has a concave-convex profile, for example. The planarization layer 20 includes an organic material layer, which may include, for example, a photoresist material, and the concave-convex profile may be prepared by an exposure process. A portion of the planarization layer 20 having the concave-convex profile includes a first convex structure 221 protruding from the planarization layer 20 in a direction away from the first substrate 10. A surface of the first convex structure 221 away from the first substrate 10 has a slope angle a, where 40°≤α≤60°. The slope angle a refers to an angle between the surface of the first convex structure 221 away from the first substrate 10 and a first direction, and 40°≤α≤60° means that the angle a between a portion of the surface of the first convex structure 221 away from the first substrate 10 and the first direction is between 40° and 60°, where the portion may include any area of the surface of the first convex structure 221 away from the first substrate 10. In this embodiment, the first direction is perpendicular to the first substrate 10.

As shown in FIG. 1, the display panel according to the present application further includes the first electrode 30, the light-emitting layer 50, and the second electrode 60. The first electrode 30 is on the planarization layer 20 away from the first substrate 10, and the first electrode 30 continues the concave-convex profile of the planarization layer 20; in other words, the first electrode 30 has a concave-convex profile conforming to the concave-convex profile of the planarization layer 20. The light-emitting layer 50 is on the first electrode 30 away from the planarization layer 20, and the light-emitting layer 50 continues the concave-convex profile of the first electrode 30; in other words, the light-emitting layer 50 has a concave-convex profile conforming to the concave-convex profile of the first electrode 30. The light-emitting layer 50 may include an OLED (Organic Light-Emitting Diode) light-emitting layer, or a QLED (Quantum Dot Light-Emitting Diode) light-emitting layer, or the like. The second electrode 60 is on the light-emitting layer 50 away from the first electrode 30, and the second electrode 60 continues the concave-convex profile of the light-emitting layer 50; in other words, the second electrode 60 has a concave-convex profile conforming to the concave-convex profile of the light-emitting layer 50. The phrase “conforming to” mentioned herein may mean “corresponding to”, “consistent with”, “similar to”, or the like. In an optional embodiment, the first electrode 30 is a transmissive electrode and the second electrode 60 is a reflective electrode. In another optional embodiment, the first electrode 30 is a reflective electrode and the second electrode 60 is a transmissive electrode.

As shown in FIG. 1, the display panel according to the present application further includes a pixel definition layer 40. The pixel definition layer 40 is provided with pixel openings to divide the display panel into a pixel area 100 and a non-pixel area 200. The portion of the planarization layer 20 having the aforementioned concave-convex profile is disposed in the pixel area 100. For example, in the first direction perpendicular to the first substrate 10, the portion of the planarization layer 20 having the concave-convex profile may overlap the pixel definition layer 40 to further improve a light extraction effect and reduce the possibility of crosstalk between neighbouring sub-pixels.

As shown in FIG. 1 and FIG. 8, in an optional embodiment, the portion of the planarization layer 20 having the concave-convex profile includes a plurality of first convex structures 221. The plurality of first convex structures 221 are located within the pixel area 100 and are distributed at an edge of the pixel area 100. That is, orthographic projections of the plurality of first convex structures 221 onto the first substrate 10 are distributed in an edge area of an orthographic projection of the pixel area 100 onto the first substrate 10, and the orthographic projections of the first convex structures 221 onto the first substrate 10 are located within the orthographic projection of the pixel area 100 onto the first substrate 10 and close to a boundary of the pixel area 100. The pixel definition layer 40 has a boss 41 in an edge area of the pixel opening, and a height of the boss 41 in the first direction is higher than that of the first convex structure 221 in the first direction.

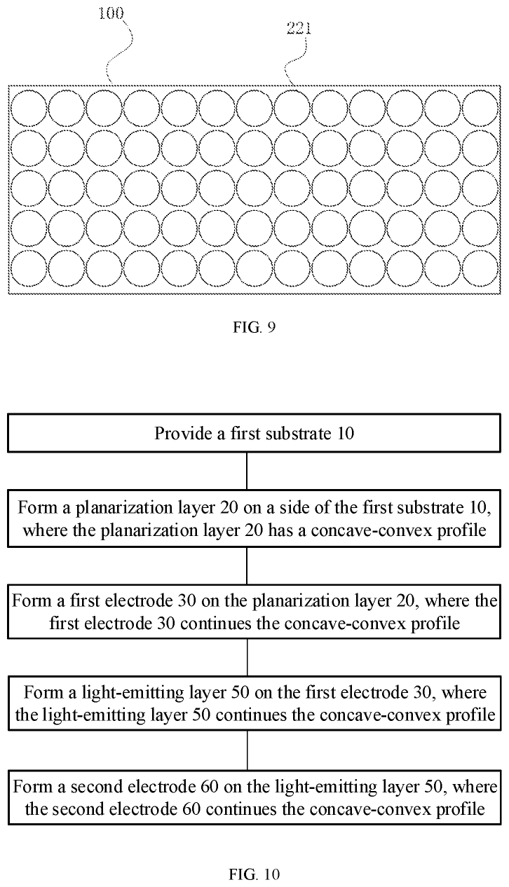

As shown in FIG. 1 and FIG. 9, in another optional embodiment, orthographic projections of the plurality of first convex structures 221 onto the first substrate 10 are distributed all over an orthographic projection of the pixel area 100 onto the first substrate 10. The specific arrangement of the plurality of first convex structures 221 is set according to actual needs. For example, the plurality of first convex structures 221 may be neatly arranged in rows and columns, or may be arranged in a honeycomb pattern. Neighbouring first convex structures 221 may be closely connected to each other, or a certain gap may be retained between neighbouring first convex structures 221. In the case that a certain gap is retained between neighbouring first convex structures 221, the maximum gap between the neighbouring first convex structures 221 is less than the maximum size of a surface of the first convex structure 221 close to the first substrate.

As shown in FIG. 1, the display panel according to the present application further includes an encapsulation layer 70. The encapsulation layer 70 is disposed on the second electrode 60 away from the light-emitting layer 50. The encapsulation layer 70 may or may not have a concave-convex profile conforming to the second electrode 60. The encapsulation layer 70 may include an inorganic encapsulation layer, such as an aluminium oxide (Al₂O₃) layer, a silicon nitride (SiNx) layer, or a silicon oxide (SiOx) layer. The encapsulation layer 70 may include an organic encapsulation layer, such as an epoxy resin layer, a polyimide (PI) layer, a polybenzimidazole (PBI) layer, or a conventional acrylic material layer. The encapsulation layer 70 may have a single-layer structure or a multi-layer stacked structure.

As shown in FIG. 1, the display panel according to the present application further includes a fill layer 80 and a second substrate 90. The fill layer 80 is disposed on the encapsulation layer 70 away from the second electrode 60 to bond the second substrate 90 to the encapsulation layer 70.

As shown in FIG. 1, in an optional embodiment, the planarization layer 20 includes a first planarization layer 21 and a second planarization layer 22. The first planarization layer 21 is disposed between the first substrate 10 and the second planarization layer 22. A side of the first planarization layer 21 close to the first substrate 10 is attached to the first substrate 10, and a side of the first planarization layer 21 away from the first substrate 10 is prepared to have a flat surface profile by steps including pre-baking, exposure, development, post-baking, and the like. The second planarization layer 22 is disposed on the first planarization layer 21 away from the first substrate 10. The second planarization layer 22 is prepared to have the first convex structures 221 by steps including pre-baking, exposure, development, post-baking, and the like. A height of the first convex structure 221 in the first direction is less than or equal to the maximum thickness of the second planarization layer 22 in the first direction. The second planarization layer 22 may or may not be exposed. A thickness of the first planarization layer 21 is greater than a thickness of the second planarization layer 22. The thickness of the first planarization layer 21 may be 1 μm to 3 μm, for example, 1 μm, 1.5 μm, 2 μm, 2.5 μm, 3 μm, etc. The thickness of the second planarization layer 22 may be 1 μm to 2 μm, for example, 1 μm, 1.3 μm, 1.5 μm, 1.7 μm, 2 μm, etc. The first planarization layer 21 and the second planarization layer 22 are both made of an organic material, such as a photoresist material. The first planarization layer 21 and the second planarization layer 22 may be made of the same photoresist material or different photoresist materials. In the case that the first planarization layer 21 and the second planarization layer 22 are made of different photoresist materials, the first planarization layer 21 may be made of a negative photoresist, and the second planarization layer 22 may be made of a positive photoresist. In this way, advantages of both the positive photoresist and the negative photoresist may be taken into account at the same time, such that the first convex structures 221 have a better profile while the planarization layer 20 has a good planarization effect. The material of the positive photoresist may include methyl methacrylate, styrene, or benzene dioxide, and the material of the negative photoresist may include nitrostyrene, styrene acrylonitrile copolymer, or styrene furazan copolymer.

As shown in FIG. 1 and FIG. 2, in an optional embodiment, the planarization layer 20 further includes an isolation layer 23. The isolation layer 23 is disposed between the first planarization layer 21 and the second planarization layer 22. The isolation layer may include an inorganic material layer, such as a silicon nitride (SiNx) material layer, a silicon oxide (SiOx) material layer, or the like. A thickness of the isolation layer 23 is 500 nm or less, and optionally, 300 nm, 350 nm, 370 nm, 400 nm, 421 nm, or the like. The isolation layer 23 is provided to effectively prevent mutual dissolution of materials between the first planarization layer 21 and the second planarization layer 22.

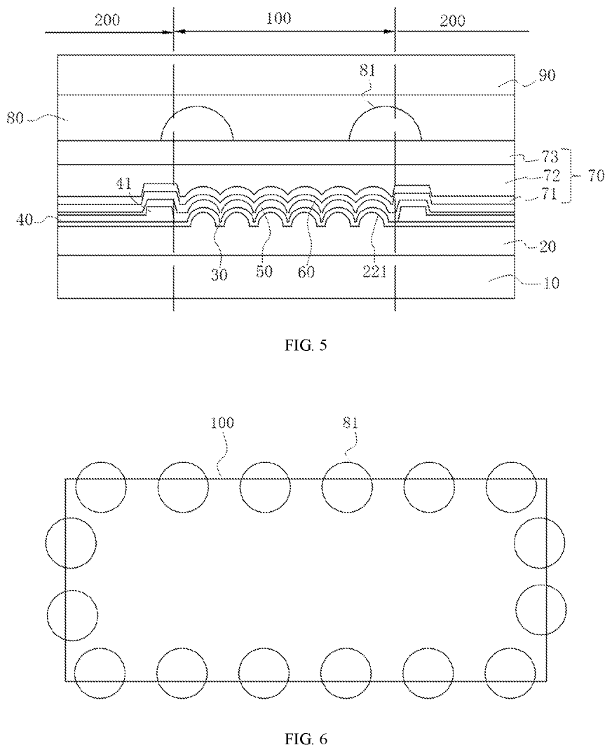

As shown in FIG. 5, in an optional embodiment, the encapsulation layer 70 includes a first inorganic encapsulation layer 71, a first organic encapsulation layer 72, and a second inorganic encapsulation layer 73. The first inorganic encapsulation layer 71 is on the second electrode 60 away from the light-emitting layer 50. A side of the first inorganic encapsulation layer 71 close to the second electrode 60 is attached to the second electrode 60, and a side of the first inorganic encapsulation layer 71 away from the second electrode 60 has a concave-convex profile conforming to the second electrode 60. The first organic encapsulation layer 72 is on the first inorganic encapsulation layer 71 away from the second electrode 60. A side of the first organic encapsulating layer 72 close to the first inorganic encapsulating layer 71 is attached to the first inorganic encapsulating layer 71, and a side of the first organic encapsulating layer 72 away from the first inorganic encapsulating layer 71 is prepared to have a flat surface. The second inorganic encapsulation layer 73 is on the first organic encapsulation layer 72 away from the first inorganic encapsulation layer 71, and opposite surfaces of the second inorganic encapsulation layer 73 are flat. The organic encapsulation layer has a refractive index n approximately equal to 1.5, and the inorganic encapsulation layer has a refractive index n approximately equal to 1.8. A lens structure 81 is disposed on the second inorganic encapsulation layer 73 away from the first organic encapsulation layer 72. The lens structure 81 may be a hemispherical or cylindrical structure with a semicircular cross section, or other structures similar to those described above. The lens structure 81 protrudes in a direction away from the second electrode 60. The fill layer 80 covers and wraps the lens structure 81, i.e., the lens structure 81 is disposed within the fill layer 80. The lens structure 81 and the fill layer 80 are made of different materials. The fill layer 80 has a refractive index n equal to 1.4, and the lens structure 81 has a refractive index greater than or equal to 1.5. For example, the refractive index of the lens structure 81 may be 1.5, 1.52, 1.55, 1.6, 1.7, etc. In this way, a light extraction angle from the first inorganic encapsulation layer 71 is optimized, while the problem that light is trapped within the first organic encapsulation layer 72 and cannot be effectively extracted is solved effectively. Moreover, the problem that the material of the first organic encapsulation layer 72 with a high refractive index is difficult to print and clogs the nozzle due to the doping of scattering particles is solved.

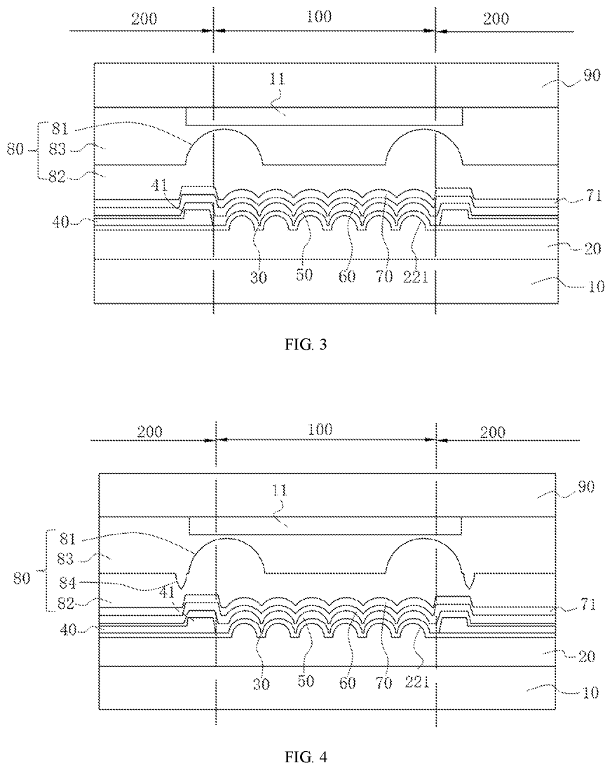

As shown in FIG. 3, in an optional embodiment, the encapsulation layer 70 includes a first inorganic encapsulation layer 71. The first inorganic encapsulation layer 71 is on the second electrode 60 away from the light-emitting layer 50. A side of the first inorganic encapsulation layer 71 close to the second electrode 60 is attached to the second electrode 60, and a side of the first inorganic encapsulation layer 71 away from the second electrode 60 has a concave-convex profile conforming to the second electrode 60. The fill layer 80 is on the first inorganic encapsulation layer 71 away from the second electrode 60. The fill layer 80 includes a first fill layer 82 and a second fill layer 83. A side of the second fill layer 83 is attached to the second substrate 90, and a side of the second fill layer 83 away from the second substrate 90 is provided with a plurality of concave structures. The concave structures may be hemispherical or cylindrical concave structures with semicircular cross sections, or other concave structures similar to those described above. The first fill layer 82 is on the second fill layer 83 away from the second substrate 90. A portion of the first fill layer 82 fills the concave structures of the second fill layer 83 to form the lens structure 81. Another portion of the first fill layer 82 bonds the second fill layer 83 to the first inorganic encapsulation layer 71. The second fill layer 83 has a refractive index n approximately equal to 1.5, and the first fill layer 82 has a refractive index n greater than or equal to 1.5 and less than or equal to 1.8, for example, the refractive index of the first fill layer 82 may be 1.5, 1.52, 1.55, 1.6, 1.8, etc. In this way, total reflection at an interface between the first inorganic encapsulation layer 71 and the first fill layer 82 is reduced, while color mixing and crosstalk are reduced by a light concentrating effect of the lens structure 81.

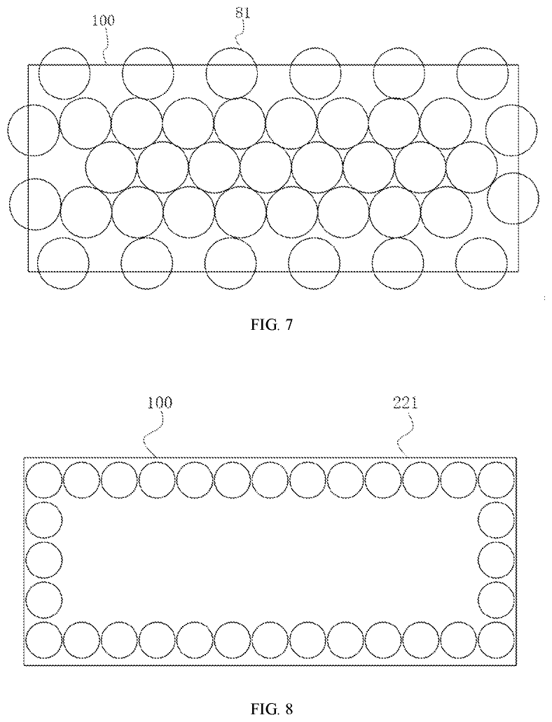

As shown in FIG. 3, FIG. 6, and FIG. 7, in an optional embodiment, the lens structure 81 is disposed on a periphery of the pixel area 100. In particular, an orthographic projection of the lens structure 81 onto the first substrate 10 overlaps the orthographic projection of the pixel area 100 onto the first substrate 10, and an area of the overlapping portion is greater than or equal to half of an area of the orthographic projection of the lens structure 81 onto the first substrate 10, and is less than the area of the orthographic projection of the lens structure 81 onto the first substrate 10. The orthographic projection of the lens structure 81 onto the first substrate 10 covers an orthographic projection of the highest point of at least one of the first convex structures 221 onto the first substrate 10. Optionally, there are a plurality of lens structures 81 disposed on a periphery of the pixel area 100. Optionally, there are a plurality of lens structures 81 disposed on a periphery of the pixel area 100 and inside the pixel area 100.

As shown in FIG. 4, in an optional embodiment, a second convex structure 84 is further provided on the second fill layer 83 away from the second substrate 90. The second convex structure 84 protrudes from a surface of the second fill layer 83 towards the second electrode 60. The first fill layer 82 covers and wraps the second convex structure 84, that is, the second convex structure 84 is disposed within the first fill layer 82. An orthographic projection of the second convex structure 84 onto the first substrate 10 is located on a side of the orthographic projection of the lens structure 81 onto the first substrate 10 away from the pixel area 100. Optionally, there are a plurality of second convex structures 84, and orthographic projections of the plurality of second convex structures 84 onto the first substrate 10 are disposed around an outer side of the orthographic projection of the lens structure 81 onto the first substrate 10. The second convex structure 84 may be in the shape of a close-packed hemisphere, a cylinder with a trapezoidal cross section, or a cylinder with a semicircular cross section. The second convex structure 84 may reflect light into the lens structure 81 through total reflection, thereby improving a light extraction efficiency while reducing color mixing and crosstalk.

As shown in FIG. 3 and FIG. 4, in an optional embodiment, the display panel according to the present application further includes a color filter layer 11. In the case that the first electrode 30 is a transmissive electrode and the second electrode 60 is a reflective electrode, the color filter layer 11 is disposed between the first substrate 10 and the planarization layer 20, and an orthographic projection of the color filter layer 11 onto the first substrate 10 covers an outer boundary of the orthographic projection of the lens structure 81 onto the first substrate 10. In the case that the first electrode 30 is a reflective electrode and the second electrode 60 is a transmissive electrode, the color filter layer 11 is disposed between the second substrate 90 and the fill layer 80, and an orthographic projection of the color filter layer 11 onto the first substrate 10 covers an outer boundary of the orthographic projection of the lens structure 81 onto the first substrate 10.

As shown in FIG. 10, the present application further discloses a method of manufacturing a display panel, including:
providing a first substrate 10; and
forming a planarization layer 20, a first electrode 30, a light-emitting layer 50, and a second electrode 60 sequentially on the first substrate 10, where the planarization layer 20 has a non-flat surface facing away from the first substrate 10, and the first electrode 30, the light-emitting layer 50, and the second electrode 60 respectively conform to the planarization layer 20. In some embodiments, the non-flat surface of the planarization layer 20 has a concave-convex profile. The first electrode 30, the light-emitting layer 50, and the second electrode 60 have concave-convex profiles respectively conforming to the concave-convex profile of the planarization layer 20.

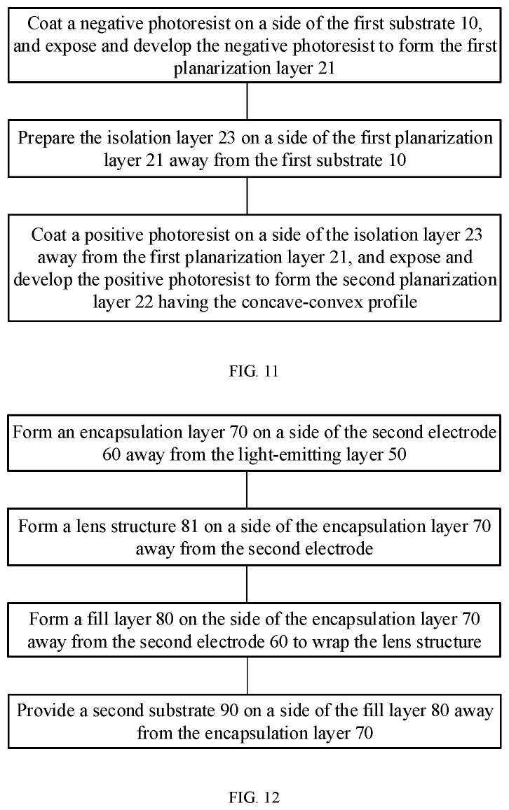

As shown in FIG. 11, in an optional embodiment, the planarization layer 20 includes a first planarization layer 21, an isolation layer 23, and a second planarization layer 22. When preparing the planarization layer 20, a negative photoresist is coated on the first substrate 10, and is exposed and developed to form the first planarization layer 21. The isolation layer 23 is prepared on the first planarization layer 21 away from the first substrate 10. A positive photoresist is coated on the isolation layer 23 away from the first planarization layer 21, and is exposed and developed to form the second planarization layer 22 having the non-flat surface. The non-flat surface includes a plurality of first convex structures 221.

As shown in FIG. 12, in an optional embodiment, the method of manufacturing the display panel further includes forming an encapsulation layer 70 on the second electrode 60 away from the light-emitting layer 50. A lens structure 81 is formed on the encapsulation layer 70 away from the second electrode. A fill layer 80 is formed on the encapsulation layer 70 away from the second electrode 60 to wrap the lens structure. A second substrate 90 is provided on the fill layer 80 away from the encapsulation layer 70.

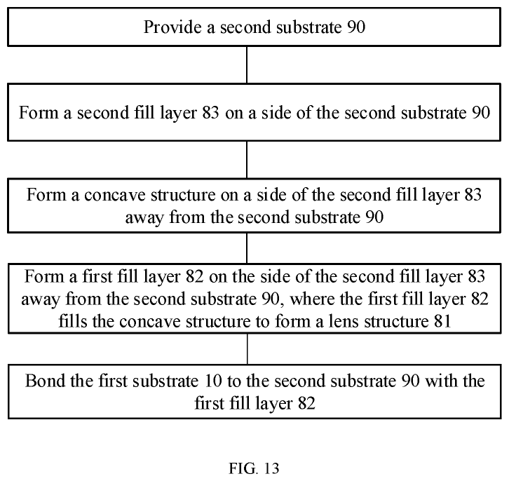

As shown in FIG. 13, in an optional embodiment, the method of manufacturing the display panel further includes providing a second substrate 90. A second fill layer 83 is formed on the second substrate 90, and the second fill layer 83 has a concave structure away from the second substrate 90. A first fill layer 82 is formed on the second fill layer 83 away from the second substrate 90, and the first fill layer 82 fills the concave structure to form a lens structure 81. The first substrate 10 is bonded to the second substrate 90 with the first fill layer 82.

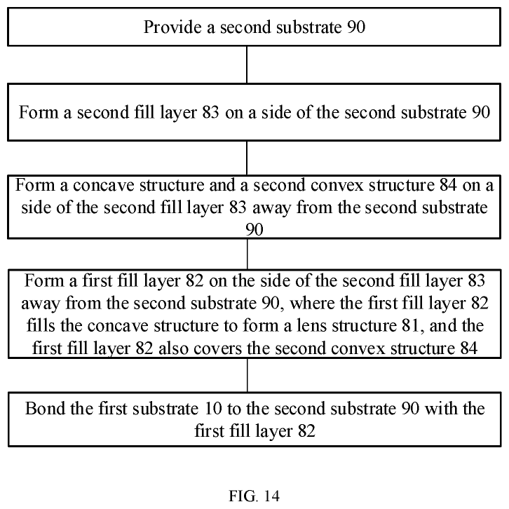

As shown in FIG. 14, in an optional embodiment, the method of manufacturing the display panel further includes providing a second substrate 90. A second fill layer 83 is formed on the second substrate 90, and a concave structure and a second convex structure 84 are formed on the second fill layer 83 away from the second substrate 90, the second convex structure 84 being on an outer side of the concave structure. A first fill layer 82 is formed on the second fill layer 83 away from the second substrate 90, and the first fill layer 82 fills the concave structure to form a lens structure 81. The first fill layer 82 also covers the second convex structure 84. The first substrate 10 is bonded to the second substrate 90 with the first fill layer 82.

Other embodiments of the specification will occur to those skilled in the art upon consideration of the specification and practice of the invention disclosed herein. This specification is intended to cover any variations, uses, or adaptations of this specification that follow the general principles of this specification and include common general knowledge or commonly used technical means in the art not disclosed in this specification. It is intended that the specification and embodiments be considered as exemplary only, with a true scope and spirit of the specification being indicated by the following claims.

It is to be understood that the specification is not limited by the precise constructions which have been described above and illustrated in the accompanying drawings, and that various modifications and changes may be made without departing from the scope thereof. The scope of the specification is limited only by the appended claims.

The foregoing are only preferred embodiments of the specification, and are not intended to limit the specification. Any modification, equivalent substitution, improvement, or the like, made within the spirit and principle of the specification shall be included in the scope of protection of the specification.

1. A display panel, comprising:
a first substrate;
a planarization layer on the first substrate and comprising a first planarization layer and a second planarization layer, the second planarization layer being farther away from the first substrate than the first planarization layer, wherein the first planarization layer has a flat surface facing the second planarization layer, and the second planarization layer has a non-flat surface facing away from the first planarization layer;
a first electrode on the planarization layer away from the first substrate, the first electrode conforming to the planarization layer;
a light-emitting layer on the first electrode away from the planarization layer, the light-emitting layer conforming to the first electrode; and
a second electrode on the light-emitting layer away from the first electrode, the second electrode conforming to the light-emitting layer.

2. The display panel according to claim 1, further comprising a pixel definition layer defining a pixel area and a non-pixel area, wherein a portion of the planarization layer is in the pixel area.

3. The display panel according to claim 2, wherein the portion of the planarization layer comprises a plurality of first convex structures that are convex towards the first electrode.

4. The display panel according to claim 3, wherein a height of each of the first convex structures in a first direction is less than or equal to a maximum thickness of the second planarization layer in the first direction, wherein the first direction is perpendicular to the first substrate.

5. The display panel according to claim 1, further comprising an isolation layer between the first planarization layer and the second planarization layer, wherein the isolation layer has a thickness less than or equal to 500 nm.

6. The display panel according to claim 3, wherein an angle between a portion of an outer surface of each of the first convex structures and a first direction is greater than or equal to 40° and less than or equal to 60°, wherein the first direction is perpendicular to the first substrate.

7. The display panel according to claim 3, wherein orthographic projections of the plurality of first convex structures onto the first substrate are distributed in an edge area of an orthographic projection of the pixel area onto the first substrate.

8. The display panel according to claim 3, wherein orthographic projections of the plurality of first convex structures onto the first substrate are distributed all over an orthographic projection of the pixel area onto the first substrate.

9. The display panel according to claim 2, further comprising a fill layer on the second electrode away from the light-emitting layer, wherein the fill layer comprises a lens structure protruding in a direction away from the second electrode.

10. The display panel according to claim 9, wherein an orthographic projection of the lens structure onto the first substrate overlaps an orthographic projection of the pixel area onto the first substrate, with an overlapping area greater than or equal to half of an area of the orthographic projection of the lens structure onto the first substrate and less than the area of the orthographic projection of the lens structure onto the first substrate, and wherein the orthographic projection of the lens structure onto the first substrate partially covers an orthographic projection of the portion of the planarization layer onto the first substrate.

11. The display panel according to claim 10, wherein the lens structure comprises a plurality of lens structures disposed on a periphery of the pixel area.

12. The display panel according to claim 9, wherein the lens structure has a refractive index greater than a refractive index of an area in the fill layer other than the lens structure.

13. The display panel according to claim 9, wherein the fill layer comprises a first fill layer on the second electrode away from the light-emitting layer, and a second fill layer on the first fill layer away from the second electrode,
wherein the lens structure is in the second fill layer, and
wherein the first fill layer comprises a second convex structure that is convex towards the second electrode, wherein an orthographic projection of the second convex structure onto the first substrate is on a side of an orthographic projection of the lens structure onto the first substrate away from the pixel area.

14. The display panel according to claim 13, wherein the second convex structure comprises a plurality of second convex structures disposed on a periphery of the lens structure.

15. The display panel according to claim 1, wherein the first electrode is a reflective electrode, and the second electrode is a transmissive electrode.

16. The display panel according to claim 1, wherein the first electrode is a transmissive electrode, and the second electrode is a reflective electrode.

17. A method of manufacturing a display panel, comprising:
forming a planarization layer, a first electrode, a light-emitting layer, and a second electrode sequentially on a first substrate, wherein the planarization layer has a non-flat surface facing away from the first substrate, and the first electrode, the light-emitting layer, and the second electrode respectively conform to the planarization layer.

18. The method according to claim 17, wherein the planarization layer comprises a first planarization layer, an isolation layer, and a second planarization layer; and
forming the planarization layer comprises:
coating a negative photoresist on the first substrate and exposing and developing the negative photoresist to form the first planarization layer;
preparing the isolation layer on the first planarization layer away from the first substrate; and
coating a positive photoresist on the isolation layer away from the first planarization layer and exposing and developing the positive photoresist to form the second planarization layer having the non-flat surface.

19. The method according to claim 17, further comprising:
forming an encapsulation layer on the second electrode away from the light-emitting layer;
forming a lens structure on the encapsulation layer away from the second electrode;
forming a fill layer on the encapsulation layer away from the second electrode to wrap the lens structure; and
providing a second substrate on the fill layer away from the encapsulation layer.

20. The method according to claim 17, further comprising:
forming a second fill layer on a second substrate, wherein the second fill layer has a concave structure away from the second substrate;
forming a first fill layer on the second fill layer away from the second substrate, wherein the first fill layer fills the concave structure to form a lens structure; and
bonding the first substrate to the second substrate with the first fill layer.
